(19) United States
(12) Patent Application Publication
(10) Pub. No.: US 2025/0390020 A1
(43) Pub. Date: Dec. 25, 2025

(54) PHOTOSENSITIVE RESIN COMPOSITION, PHOTOSENSITIVE ELEMENT, CURED PRODUCT, METHOD FOR FORMING RESIST PATTERN, AND METHOD FOR MANUFACTURING PRINTED WIRING BOARD

(71) Applicant: Resonac Corporation, Tokyo (JP)

(72) Inventors: Shiho TANAKA, Tokyo (JP); Keishi ONO, Tokyo (JP); Mao NARITA, Tokyo (JP); Akiko TAKEDA, Tokyo (JP)

(21) Appl. No.: 18/859,375

(22) PCT Filed: Mar. 1, 2024
(86) PCT No.: PCT/JP2024/007815

§ 371 Date: Oct. 23, 2024

(30) Foreign Application Priority Data
Mar. 10, 2023 (WO) PCT/JP2023/009338

(51) Int. Cl. G03F 7/031; G03F 7/033; H05K 3/18

(52) U.S. Cl. CPC G03F 7/031; G03F 7/033; H05K 3/188; H05K 2203/0548

(57) ABSTRACT

A photosensitive resin composition, containing: a binder polymer (A); a photopolymerizable compound (B) having at least one ethylenically unsaturated bond; and a photopolymerization initiator (C), in which the photopolymerization initiator (C) includes an oxime ester-based photopolymerization initiator, and a content of the oxime ester-based photopolymerization initiator is 0.3 parts by mass or more, with respect to a total of 100 parts by mass of the binder polymer (A) and the photopolymerizable compound (B).

### TECHNICAL FIELD

The present disclosure relates to a photosensitive resin composition, a photosensitive element, a cured product, a method for forming a resist pattern, and a method for producing a printed circuit board.

### BACKGROUND ART

In the field of producing a printed circuit board, a photosensitive element including a layer (hereinafter, referred to as a “photosensitive resin layer”) formed on a support by using a photosensitive resin composition as a resist material used for an etching treatment, a plating treatment, or the like is widely used.

In the related art, the printed circuit board, for example, is produced in the following procedure by using the photosensitive element. That is, first, the photosensitive resin layer of the photosensitive element is laminated on a substrate for forming a circuit (such as a copper clad laminate). In this case, the lamination is performed such that the photosensitive resin layer is closely attached to the surface of the substrate for forming a circuit, on which a conductor pattern (a circuit) is formed. In addition, the lamination is performed by thermally crimping the photosensitive resin layer to the substrate for forming a circuit as a base (a normal pressure laminating method).

Next, a desired region of the photosensitive resin layer is exposed via a mask film or the like (a mask exposure method). In this case, the support (such as a support film) is peeled at a timing either before exposure or after exposure. After that, the unexposed portion of the photosensitive resin layer is dissolved or dispersed with a developer, and removed to form a resist pattern consisting of the cured portion of the photosensitive resin layer. Next, the conductor pattern is formed by performing an etching treatment or a plating treatment, and then, finally, the resist pattern is peeled and removed.

However, as a method for exposing the pattern described above, recently, a direct writing method (such as a laser direct imaging (LDI) method) for directly writing circuit data created by CAD with laser light, without using a mask film, has been widespread.

In the direct writing method (the LDI method or the like), since the mask film is not used, there are many advantages that the cost of the mask film can be reduced, the positioning accuracy of the opening portion of the resist is high, scaling correction is easily performed, and the management of impurity attachment, a stain, and a damage with respect to the mask is not required.

As the photosensitive resin composition that can be used for such a direct writing method, for example, a photosensitive resin composition containing a specific binder polymer, and a specific photopolymerization initiator is proposed (for example, refer to Patent Literatures 1 and 2 described below).

### CITATION LIST

### Patent Literature

Patent Literature 1: Japanese Unexamined Patent Publication No. 2010-217400
Patent Literature 2: International Publication WO 2012/014580
Patent Literature 3: Japanese Unexamined Patent Publication No. H11-327137

### SUMMARY OF INVENTION

### Technical Problem

In both of the mask exposure method and the direct writing method, it is necessary to accurately form the resist pattern in order to form fine wiring. However, in the case of forming the resist pattern by using the photosensitive resin composition of the related art, there is a problem that a resist line width after exposure and development is likely to be greater than a designed value.

Therefore, an object of the present disclosure is to provide a photosensitive resin composition capable of reducing a deviation of an obtained resist line width from a designed value when forming a resist pattern. In addition, another object of the present disclosure is to provide a photosensitive element, a cured product, a method for forming a resist pattern, and a method for producing a printed circuit board, using the photosensitive resin composition.

### Solution to Problem

In order to attain the objects described above, the present disclosure provides a photosensitive resin composition, a photosensitive element, a cured product, a method for forming a resist pattern, and a method for producing a printed circuit board described below.
[1] A photosensitive resin composition, containing: a binder polymer (A); a photopolymerizable compound (B) having at least one ethylenically unsaturated bond; and a photopolymerization initiator (C), in which the photopolymerization initiator (C) includes an oxime ester-based photopolymerization initiator, and a content of the oxime ester-based photopolymerization initiator is 0.3 parts by mass or more, with respect to a total of 100 parts by mass of the binder polymer (A) and the photopolymerizable compound (B).
[2] The photosensitive resin composition according to [1] described above, in which the binder polymer (A) has a structural unit derived from a (meth)acrylic acid, and a structural unit derived from benzyl (meth)acrylate or a benzyl (meth)acrylate derivative.
[3] The photosensitive resin composition according to [1] or [2] described above, in which the photopolymerization initiator (C) consists of only the oxime ester-based photopolymerization initiator.
[4] The photosensitive resin composition according to any one of [1] to [3] described above, in which the oxime ester-based photopolymerization initiator includes a compound having a carbazole structure.
[5] The photosensitive resin composition according to any one of [1] to [4] described above, in which the oxime ester-based photopolymerization initiator includes a compound having a phenyl sulfide structure.
[6] The photosensitive resin composition according to any one of [1] to [5] described above, in which the oxime ester-based photopolymerization initiator includes a compound having a fluorene structure.
[7] The photosensitive resin composition according to any one of [1] to [6] described above, in which the content of the oxime ester-based photopolymerization initiator is 3.0 parts by mass or less, with respect to a total of 100 parts by mass of the binder polymer (A) and the photopolymerizable compound (B).
[8] The photosensitive resin composition according to any one of [1] to [7] described above, in which the photosensitive resin composition is used for a direct writing method.
[9] A photosensitive element, including: a support; and a photosensitive resin layer disposed on the support, in which the photosensitive resin layer includes the photosensitive resin composition according to any one of [1] to [8] described above or a cured product thereof.
[10] A cured product of the photosensitive resin composition according to any one of [1] to [8] described above.
[11] The cured product according to described above, in which the cured product is a resist pattern.
[12] A method for forming a resist pattern, including: a step of forming a photosensitive resin layer on a base material by using the photosensitive resin composition according to any one of [1] to [8] described above; a step of irradiating at least a part of the photosensitive resin layer with an active ray to cure the photosensitive resin layer; and a step of removing an uncured portion of the photosensitive resin layer from the base material to form a resist pattern.
[13] A method for forming a resist pattern, including: a step of forming a photosensitive resin layer on a base material by using the photosensitive element according to [9] described above; a step of irradiating at least a part of the photosensitive resin layer with an active ray to cure the photosensitive resin layer; and a step of removing an uncured portion of the photosensitive resin layer from the base material to form a resist pattern.
[14] A method for producing a printed circuit board, including: a step of forming a resist pattern on the base material by the method for forming

a resist pattern according to or described above; and a step of performing a plating treatment or an etching treatment on a member having the base material and the resist pattern.

### Advantageous Effects of Invention

According to the present disclosure, it is possible to provide the photosensitive resin composition capable of reducing the deviation of the obtained resist line width from the designed value when forming the resist pattern. In addition, according to the present disclosure, it is possible to provide the photosensitive element, the cured product, the method for forming a resist pattern, and the method for producing a printed circuit board, using the photosensitive resin composition.

### BRIEF DESCRIPTION OF DRAWINGS

FIG. 1 is a schematic cross-sectional view illustrating a photosensitive element according to one embodiment of the present disclosure.

FIG. 2 is a perspective view schematically illustrating an example of a step of producing a printed circuit board by a semi-additive method.

### DESCRIPTION OF EMBODIMENTS

Hereinafter, an embodiment of the present disclosure will be described in detail. It is to be understood that other embodiments can be considered and devised without departing from the scope and gist of the present disclosure. Therefore, the following detailed description in “Description of Embodiments” is not to be understood in a limiting sense.

In this specification, the term “step” includes not only an independent step but also a step that is not explicitly distinguishable from other steps insofar as a desired function of the step is attained. A numerical range represented by using “to” indicates a range including numerical values described before and after “to” as the minimum value and the maximum value, respectively. In numerical ranges described in stages in this specification, the upper limit value or the lower limit value of a numerical range in a certain stage may be replaced with the upper limit value or the lower limit value of a numerical range in the other stage. In the numerical range described in this specification, the upper limit value or the lower limit value of the numerical range may be replaced with values described in Examples. The term “layer” includes not only a structure in which a layer is formed on the entire surface but also a structure in which a layer is formed on a part of the surface when observed as a plan view. A “(meth)acrylic acid” indicates at least one of an “acrylic acid” and a “methacrylic acid” corresponding thereto. The same also applies to other similar expressions such as (meth)acrylate.

In this specification, in a case where there are a plurality of substances corresponding to each component in a composition, the amount of each component in the composition indicates the total amount of the plurality of substances in the composition, unless otherwise specified. In this specification, a “room temperature” indicates 25° C. In this specification, a “solid content” indicates a non-volatile content excluding a volatile substance (water, a solvent, or the like) in a photosensitive resin composition. That is, the “solid content” indicates a component other than the solvent such as water or an organic solvent, which remains without being volatilized in a drying step, and also includes a substance in the form of a liquid, syrup, or a wax approximately at a room temperature (25° C.).

A “(poly) oxyethylene group” indicates an oxyethylene group, or a polyoxyethylene group in which two or more ethylene groups are linked by an ether bond. A “(poly) oxypropylene group” indicates an oxypropylene group, or a polyoxypropylene group in which two or more propylene groups are linked by an ether bond. “EO-modified” indicates a compound having a (poly) oxyethylene group. “PO-modified” indicates a compound having a (poly) oxypropylene group. “EO/PO-modified” indicates a compound having both of a (poly) oxyethylene group and a (poly) oxypropylene group.

### <Photosensitive Resin Composition and Cured Product Thereof>

A photosensitive resin composition according to this embodiment contains a binder polymer (A) (hereinafter, also referred to as a component (A)), a photopolymerizable compound (B) having at least one ethylenically unsaturated bond (hereinafter, also referred to as a component (B)), and a photopolymerization initiator (C) (hereinafter, also referred to as a component (C)). In the photosensitive resin composition according to this embodiment, the photopolymerization initiator (C) includes an oxime ester-based photopolymerization initiator. In the photosensitive resin composition according to this embodiment, the content of the oxime ester-based photopolymerization initiator is 0.3 parts by mass or more, with respect to a total of 100 parts by mass of the binder polymer (A) and the photopolymerizable compound (B).

By the photosensitive resin composition according to this embodiment containing 0.3 parts by mass or more of the oxime ester-based photopolymerization initiator as the component (C), with respect to a total of 100 parts by mass of the component (A) and the component (B), in both of a mask exposure method and a direct writing method, it is possible to prevent an obtained resist line width from being greater or less than a designed value when forming a resist pattern, and reduce the deviation of the obtained resist line width from the designed value. In the related art, it is necessary to correct writing data or a mask film by considering that the resist line width is greater or less than the designed value in a case where the deviation of the obtained resist line width from the designed value is large, but by using the photosensitive resin composition according to this embodiment, it is possible to obtain the resist line width close to the designed value even without correction. Therefore, since it is not necessary to correct the designed value in an exposure process, or only minor correction is required, it is possible to efficiently perform the exposure process.

A cured product according to this embodiment is a cured product of the photosensitive resin composition according to this embodiment. The cured product according to this embodiment may be a resist pattern.

### (Component (A): Binder Polymer)

Examples of the component (A) that can be used for the photosensitive resin composition according to this embodiment include a (meth)acrylic resin (a resin having a structural unit derived from a (meth)acrylic acid), a styrene-based resin, an epoxy-based resin, an amide-based resin, an amide epoxy-based resin, an alkyd-based resin, and a phenol-based resin. From the viewpoint of further improving an alkali developing property, the photosensitive resin composition according to this embodiment may contain a (meth)acrylic resin, and the component (A) may have a structural unit derived from a (meth)acrylic acid. In addition, the component (A) may have a structural unit derived from a polymerizable monomer other than the (meth)acrylic acid. Examples of such a structural unit include a structural unit derived from styrene or a styrene derivative, a structural unit derived from alkyl(meth)acrylate, a structural unit derived from benzyl (meth)acrylate or a benzyl (meth)acrylate derivative, and the like. From the viewpoint of improving a resolution and adhesiveness, it is preferable that the component (A) has at least a structural unit derived from a (meth)acrylic acid, and a structural unit derived from benzyl (meth)acrylate or a benzyl (meth)acrylate derivative. In addition, from the viewpoint of further improving the resolution and the adhesiveness, the component (A) may have a structural unit derived from hydroxyalkyl (meth)acrylate. In addition, the component (A) may be configured of only at least one type of structural unit selected from the group consisting of a structural unit derived from a (meth)acrylic acid, a structural unit derived from styrene or a styrene derivative, a structural unit derived from alkyl(meth)acrylate, a structural unit derived from benzyl (meth)acrylate or a benzyl (meth)acrylate derivative, and a structural unit derived from hydroxyalkyl (meth)acrylate. Note that the component (A), for example, can be produced by the radical polymerization of the polymerizable monomer.

Examples of the polymerizable monomer other than the (meth)acrylic acid include styrene; a polymerizable styrene derivative that can be substituted at an-position or an aromatic ring, such as vinyl toluene and «-methyl styrene; alkyl(meth)acrylate; benzyl(meth)acrylate; a benzyl (meth)acrylate derivative; acryl amide such as diacetone acryl amide; acrylonitrile; esters of vinyl alcohol such as vinyl-n-butyl ether; cycloalkyl(meth)acrylate; furfuryl(meth)acrylate; tetrahydrofurfuryl(meth)acrylate; isobornyl(meth)acrylate; adamantyl(meth)acrylate; dicyclopentanyl(meth)acrylate; dimethyl aminoethyl(meth)acrylate; diethyl aminoethyl(meth)acrylate; glycidyl(meth)acrylate; 2,2,2-trifluoroethyl(meth)acrylate; 2,2,3,3-tetrafluoropropyl(meth)acrylate; a β-furyl(meth)acrylic acid; a β-styryl(meth)acrylic acid; a maleic acid; a maleic anhydride; maleic acid monoester such as monomethyl maleate, monoethyl maleate, and monoisopropyl maleate; a fumaric acid; a cinnamic acid; an a-cyanocinnamic acid; an itaconic acid; a crotonic acid; a propiolic acid, and the like.

Examples of the benzyl (meth)acrylate derivative may include a compound in which an alkoxy group having 1 to 6 carbon atoms (the number of carbon atoms, the same applies below), a halogen atom, and/or an alkyl group having 1 to 6 carbon atoms are substituted at an aromatic ring of a benzyl group. Examples of the benzyl (meth)acrylate derivative include ethoxybenzyl(meth)acrylate, methoxybenzyl(meth)acrylate, chlorobenzyl(meth)acrylate, methyl benzyl(meth)acrylate, and ethyl benzyl (meth)acrylate.

The component (A), from the viewpoint of further improving the resolution and the adhesiveness, may have at least one type of structural unit derived from styrene or a styrene derivative. In this case, by further improving the resolution, it is possible to obtain a more excellent resist shape. The component (A) may have a structural unit derived from styrene, and a structural unit derived from a styrene derivative.

Examples of the hydroxyalkyl (meth)acrylate include hydroxymethyl(meth)acrylate, hydroxyethyl(meth)acrylate, hydroxypropyl(meth)acrylate, hydroxybutyl(meth)acrylate, hydroxypentyl(meth)acrylate, hydroxyhexyl(meth)acrylate, and the like. In addition, in a case where the number of carbon atoms of an alkyl part in the hydroxyalkyl (meth)acrylate unit is 3 or more, the alkyl part may have a branched structure.

The component (A), from the viewpoint of improving the alkali developing property and a peeling property, may have at least one type of structural unit derived from alkyl (meth)acrylate. Examples of an alkyl group of the alkyl (meth)acrylate include a methyl group, an ethyl group, a propyl group, a butyl group, a pentyl group, a hexyl group, a heptyl group, an octyl group, a nonyl group, a decyl group, an undecyl group, and a dodecyl group. As the alkyl group, each structural isomer can be used. Examples of the alkyl (meth)acrylate include methyl(meth)acrylate, ethyl(meth)acrylate, propyl(meth)acrylate, butyl(meth)acrylate, pentyl(meth)acrylate, hexyl(meth)acrylate, heptyl(meth)acrylate, octyl(meth)acrylate, 2-ethyl hexyl(meth)acrylate, nonyl(meth)acrylate, decyl(meth)acrylate, undecyl(meth)acrylate, and dodecyl (meth)acrylate. The number of carbon atoms of the alkyl group, from the viewpoint of further improving the peeling property, may be 1 to 4. Only one type of the alkyl (meth)acrylate can be used alone, or two or more types thereof can be used in combination.

The content of each structural unit configuring the component (A) is not particularly limited. The content of the structural unit derived from the (meth)acrylic acid may be a content at which the acid value of the component (A) is in the following range. The acid value of the component (A), from the viewpoint of preventing a developing time from being lengthened, may be 100 mgKOH/g or more, 120 mgKOH/g or more, 140 mgKOH/g or more, 150 mgKOH/g or more, or 160 mgKOH/g or more. The acid value of the component (A), from the viewpoint of further improving the developer resistance (for example, the adhesiveness) of the cured product of the photosensitive resin composition, may be 250 mgKOH/g or less, 240 mgKOH/g or less, or 230 mgKOH/g or less. From such a viewpoint, the acid value of the component (A) may be 100 to 250 mgKOH/g, 120 to 240 mgKOH/g, 140 to 230 mgKOH/g, 150 to 230 mgKOH/g, or 160 to 230 mgKOH/g. Note that in the case of performing solvent development, from the viewpoint of being excellent in a developing property, the amount of polymerizable monomer having a carboxy group (a monomer, such as a (meth)acrylic acid) may be adjusted to be small.

In a case where the component (A) has a structural unit derived from benzyl (meth)acrylate or a benzyl (meth)acrylate derivative, the content of the structural unit may be in the following range, on the basis of the total solid content (the total mass) of the component (A). The content, from the viewpoint of improving the chemical resistance of a resin, may be 1% by mass or more, 15% by mass or more, or 20% by mass or more. The content, from the viewpoint of preventing the peeling time from being lengthened, may be 80% by mass or less, 50% by mass or less, or 40% by mass or less. From such a viewpoint, the content may be 1 to 80% by mass, 15 to 50% by mass, or 20 to 40% by mass.

In a case where the component (A) has a structural unit derived from styrene or a styrene derivative, the content of the structural unit may be in the following range, on the basis of the total solid content (the total mass) of the component (A). The content, from the viewpoint of further improving the resolution, may be 5% by mass or more, 10% by mass or more, 20% by mass or more, 25% by mass or more, 30% by mass or more, 35% by mass or more, 40% by mass or more, or 45% by mass or more. The content, from the viewpoint of preventing a peeled piece from being enlarged and the peeling time from being lengthened, may be 65% by mass or less, 55% by mass or less, or 50% by mass or less. From such a viewpoint, the content may be 5 to 65% by mass, 10 to 55% by mass, 20 to 50% by mass, 25 to 50% by mass, 30 to 50% by mass, 35 to 50% by mass, 40 to 50% by mass, or 45 to 50% by mass.

The component (A) may have a structural unit derived from benzyl (meth)acrylate or a benzyl (meth)acrylate derivative, and a structural unit derived from styrene or a styrene derivative. In this case, it is possible to obtain a resist more excellent in the adhesiveness.

In a case where the component (A) has a structural unit derived from alkyl(meth)acrylate, the content of the structural unit may be in the following range, on the basis of the total solid content (the total mass) of the component (A). The content, from the viewpoint that it is possible to prevent the peeled piece from being enlarged and prevent the peeling time from being lengthened, may be 1% by mass or more, 2% by mass or more, or 3% by mass or more. The content, from the viewpoint of further improving the resolution and the adhesiveness, may be 80% by mass or less, 60% by mass or less, or 50% by mass or less. From such a viewpoint, the content may be 1 to 80% by mass, 2 to 60% by mass, or 3 to 50% by mass.

The weight average molecular weight (Mw) of the component (A), from the viewpoint that the developer resistance (for example, the adhesiveness) of the cured product of the photosensitive resin composition tends to be more excellent, may be 10000 or more, 20000 or more, or 25000 or more. The weight average molecular weight (Mw) of the component (A), from the viewpoint that there is a tendency of being excellent in the developing time, may be 100000 or less, 80000 or less, or 60000 or less. From such a viewpoint, the weight average molecular weight (Mw) of the component (A) may be 10000 to 100000, 20000 to 80000, or 25000 to 60000. Note that the weight average molecular weight of the component (A) is measured by gel permeation chromatography (GPC) (converted by a calibration curve using standard polystyrene). Note that in a case where it is difficult to measure the weight average molecular weight of a low-molecular-weight compound by the measurement method described above, the molecular weight can also be measured by other methods, and the average thereof can be calculated.

The degree (Mw/Mn) of dispersion of the component (A) is not particularly limited, and may be 1.0 to 3.0, or 1.5 to 2.5. In a case where the degree of dispersion is 3.0 or less, the adhesiveness and the resolution are further improved.

The component (A), as necessary, may have a characteristic group (such as a nitro group) with photosensitivity to light having a wavelength in a range of 350 to 440 nm in the molecules.

In the photosensitive resin composition according to this embodiment, as the component (A), only one type of binder polymer may be used alone, or two or more types of binder polymers may be used in any combination. In a case where two or more types of binder polymers are used in combination, examples of the component (A) include two or more types of binder polymers consisting of different copolymerization components (binder polymers having different monomer units as a copolymerization component), two or more types of binder polymers having different weight average molecular weights, and two or more types of binder polymers having different degrees of dispersion. As the component (A), a polymer having a multimodal molecular weight distribution described in Japanese Unexamined Patent Publication No. H11-327137 (Patent Literature 3) can also be used.

The content of the component (A) may be in the following range, on the basis of the total solid content (the total mass) of the photosensitive resin composition. The content of the component (A), from the viewpoint that there is a tendency of being excellent in the moldability of a film, may be 20% by mass or more, 30% by mass or more, 40% by mass or more, or 50% by mass or more. The content of the component (A), from the viewpoint that there is a tendency of being more excellent in a sensitivity and the resolution, may be 90% by mass or less, 80% by mass or less, 65% by mass or less, or 60% by mass or less. From such a viewpoint, the content of the component (A) may be 20 to 90% by mass, 30 to 80% by mass, 40 to 65% by mass, or 50 to 60% by mass.

The content of the component (A) may be in the following range, with respect to 100 parts by mass of the total amount of the component (A) and the component (B). The content of the component (A), from the viewpoint of further improving the formability of the film, may be 30 parts by mass or more, 35 parts by mass or more, 40 parts by mass or more, or 50 parts by mass or more. The content of the component (A), from the viewpoint of further improving the sensitivity and the resolution, may be 70 parts by mass or less, 65 parts by mass or less, or 60 parts by mass or less. From such a viewpoint, the content of the component (A) may be 30 to 70 parts by mass, 35 to 65 parts by mass, 40 to 60 parts by mass, or 50 to 60 parts by mass.

### (Component (B): Photopolymerizable Compound)

The component (B) is a compound having at least one ethylenically unsaturated bond. Only one type of the component (B) can be used alone, or two or more types thereof can be used in combination. The component (B), from the viewpoint of further improving the alkali developing property, the resolution, and the peeling property after curing, may include at least one type of bisphenol A-type (meth)acrylate compound.

Examples of the bisphenol A-type (meth)acrylate compound include 2,2-bis(4-((meth)acryloxypolyethoxy)phenyl) propane, 2,2-bis(4-((meth)acryloxypolypropoxy)phenyl) propane, 2,2-bis(4-((meth)acryloxypolybutoxy)phenyl) propane, 2,2-bis(4-((meth)acryloxypolyethoxypolypropoxy)phenyl) propane, and the like. Among them, the component (B), from the viewpoint of further improving the resolution and the peeling property, may include the 2,2-bis(4-((meth)acryloxypolyethoxy)phenyl) propane. Only one type of the bisphenol A-type (meth)acrylate compound can be used alone, or two or more types thereof can be used in combination.

Among them, the 2,2-bis(4-(methacryloxydiethoxy)phenyl) propane is commercially available as BPE-200 (manufactured by SHIN-NAKAMURA CHEMICAL CO., LTD., Product Name). The 2,2-bis(4-(methacryloxypentaethoxy)phenyl) propane is commercially available as BPE-500 (manufactured by SHIN-NAKAMURA CHEMICAL CO., LTD., Product Name) or FA-321M (manufactured by Resonac Corporation., Product Name).

In the photosensitive resin composition according to this embodiment, the content of the bisphenol A-type (meth)acrylate compound, from the viewpoint of further improving the resolution of the resist pattern may be in the following range, on the basis of the total solid content (the total mass) of the component (B). The content may be 20% by mass or more, 40% by mass or more, 60% by mass or more, or 70% by mass or more. The content may be 100% by mass or less, or 95% by mass or less. From such a viewpoint, the content may be 20 to 100% by mass, 40 to 100% by mass, 60 to 100% by mass, or 70 to 100% by mass, or may be 20 to 95% by mass, 40 to 95% by mass, 60 to 95% by mass, or 70 to 95% by mass.

The component (B), from the viewpoint of improving the resolution and flexibility in a balanced way, may include a compound obtained by a reaction between polyhydric alcohol and an α,β-unsaturated carboxylic acid. Examples of the compound obtained by the reaction between the polyhydric alcohol and the α,β-unsaturated carboxylic acid include polyethylene glycol di(meth)acrylate of which the number of ethylene groups is 2 to 14; polypropylene glycol di(meth)acrylate of which the number of propylene groups is 2 to 14; alkylene glycol di(meth)acrylate having both of a (poly) oxyethylene group and a (poly) oxypropylene group; trimethylol propane di(meth)acrylate; trimethylol propane tri (meth)acrylate; EO-modified trimethylol propane tri (meth)acrylate; PO-modified trimethylol propane tri (meth)acrylate; EO/PO-modified trimethylol propane tri (meth)acrylate; tetramethylol methane tri (meth)acrylate; and tetramethylol methane tetra(meth)acrylate. Only one type of the compound can be used alone, and from the viewpoint of further improving the resolution, two or more types selected from the group consisting of the compound obtained by the reaction between the polyhydric alcohol and the α,β-unsaturated carboxylic acid may be used in combination. In a case where two or more types of compounds are combined, the resolution is further improved.

The content (the total amount) of the compound obtained by the reaction between the polyhydric alcohol and the α,β-unsaturated carboxylic acid may be in the following range, on the basis of the total solid content (the total mass) of the component (B). The content, from the viewpoint of improving the flexibility, may be 5% by mass or more. The content, from the viewpoint of further improving the resolution, may be 20% by mass or less, or 15% by mass or less. From such a viewpoint, the content may be 5 to 20% by mass, or 5 to 15% by mass.

The photosensitive resin composition of this embodiment may further contain other polymerizable compounds in addition to the bisphenol A-type (meth)acrylate compound and the compound obtained by the reaction between the polyhydric alcohol and the α,β-unsaturated carboxylic acid, as the component (B).

Examples of the other polymerizable compound include nonyl phenoxypolyethylene oxy (meth)acrylate, a phthalic acid-based compound, alkyl(meth)acrylate, a photopolymerizable compound having at least one cationic polymerizable cyclic ether group in the molecules (such as an oxetane compound), and the like. Among them, from the viewpoint of improving the resolution, the adhesiveness, the resist shape, and the peeling property after curing in a balanced way, at least one type selected from the group consisting of the nonyl phenoxypolyethylene oxy (meth)acrylate and the phthalic acid-based compound is preferable.

Examples of the nonyl phenoxypolyethylene oxy (meth)acrylate include nonyl phenoxytriethylene oxy (meth)acrylate, nonyl phenoxytetraethylene oxy (meth)acrylate, nonyl phenoxypentaethylene oxy (meth)acrylate, nonyl phenoxyhexaethylene oxy (meth)acrylate, nonyl phenoxyheptaethylene oxy (meth)acrylate, nonyl phenoxyoctaethylene oxy (meth)acrylate, nonyl phenoxynonaethylene oxy (meth)acrylate, nonyl phenoxydecaethylene oxy (meth)acrylate, and nonyl phenoxyundecaethylene oxy (meth)acrylate. Only one type of the nonyl phenoxypolyethylene oxy (meth)acrylate can be used alone, or two or more types thereof can be used in combination.

Examples of the phthalic acid-based compound include Y-chloro-β-hydroxypropyl-β′-(meth)acryloyl oxyethyl-o-phthalate, β-hydroxyethyl-β′-(meth)acryloyl oxyethyl-o-phthalate, and β-hydroxypropyl-β′-(meth)acryloyl oxyethyl-o-phthalate. Among them, the γ-chloro-β-hydroxypropyl-β′-(meth)acryloyl oxyethyl-o-phthalate is preferable as the phthalic acid-based compound. The γ-chloro-β-hydroxypropyl-β′-methacryloyl oxyethyl-o-phthalate is commercially available as FA-MECH (manufactured by Resonac Corporation., Product Name). Only one type of the phthalic acid-based compound can be used alone, or two or more types thereof can be used in combination.

In a case where the photosensitive resin composition according to this embodiment contains the other photopolymerizable compound described above as the component (B), the content of the photopolymerizable compound, from the viewpoint of improving the resolution, the adhesiveness, the resist shape, and the peeling property after curing in a balanced way, may be 1 to 30% by mass, 3 to 25% by mass, or 5 to 20% by mass, on the basis of the total solid content (the total mass) of the component (B).

The content of the component (B) may be in the following range, on the basis of the total solid content (the total mass) of the photosensitive resin composition. The content of the component (B), from the viewpoint that there is a tendency of being more excellent in the sensitivity and the resolution, may be 3% by mass or more, 10% by mass or more, 25% by mass or more, 30% by mass or more, or 40% by mass or more. The content of the component (B), from the viewpoint that there is a tendency of being excellent in the moldability of the film, may be 70% by mass or less, 60% by mass or less, or 50% by mass or less. From such a viewpoint, the content of the component (B) may be 3 to 70% by mass, 10 to 60% by mass, 25 to 50% by mass, 30 to 50% by mass, or 40 to 50% by mass.

The content of the component (B) may be in the following range, with respect to 100 parts by mass of the total amount of the component (A) and the component (B). The content of the component (B), from the viewpoint of further improving the sensitivity and the resolution, may be 5 parts by mass or more, 10 parts by mass or more, 15 parts by mass or more, 20 parts by mass or more, 30 parts by mass or more, or 40 parts by mass or more. The content of the component (B), from the viewpoint of further improving the formability of the film, may be 70 parts by mass or less, 65 parts by mass or less, 60 parts by mass or less, 50 parts by mass or less, or 45 parts by mass or less. From such a viewpoint, the content of the component (B) may be 5 to 70 parts by mass, 10 to 70 parts by mass, 15 to 65 parts by mass, 20 to 60 parts by mass, 30 to 50 parts by mass, or 40 to 45 parts by mass.

### (Component (C): Photopolymerization Initiator)

The photosensitive resin composition according to this embodiment contains the oxime ester-based photopolymerization initiator as the component (C). Accordingly, in both of the mask exposure method and the direct writing method, it is possible to reduce the deviation of the obtained resist line width from the designed value when forming the resist pattern.

The oxime ester-based photopolymerization initiator is not particularly limited insofar as the oxime ester-based photopolymerization initiator is a photopolymerization initiator having an oxime ester group, and a compound having at least one type of a carbazole structure, a phenyl sulfide structure, and a fluorene structure is preferable. Accordingly, in both of the mask exposure method and the direct writing method, it is possible to reduce the deviation of the obtained resist line width from the designed value when forming the resist pattern. Only one type of the oxime ester-based photopolymerization initiator can be used alone, or two or more types thereof can be used in combination.

Examples of the oxime ester-based photopolymerization initiator having a carbazole structure include 1-propanone, 3-cyclopentyl-1-[9-ethyl-6-(2-methyl benzoyl)-9H-carbazol-3-yl]-, 1-(o-acetyl oxime) (Product Name “TR-PBG-304”, manufactured by Changzhou Tronly New Electronic Materials Co., Ltd.), 1-propanone, 3-cyclopentyl-1-[2-(2-pyrimidinyl thio)-9H-carbazol-3-yl]-, 1-(o-acetyl oxime) (Product Name “TR-PBG-314”, manufactured by Changzhou Tronly New Electronic Materials Co., Ltd.), 2-(acetoxyimino)-1-(6-(2-(acetoxyimino)-3-cyclohexyl propionyl)-9-ethyl carbazol-3-yl) n-octan-1-one, and the like. Examples of a commercially available product include TR-PBG-304, TR-PBG-314, and TR-PBG-345 (all are manufactured by Changzhou Tronly New Electronic Materials Co., Ltd.), and the like.

Examples of the oxime ester-based photopolymerization initiator having a phenyl sulfide structure include 1-[4-(phenyl thio) phenyl]-3-cyclopentyl propane-1,2-dione-2-(o-benzoyl oxime) (Product Name “TR-PBG-305”, manufactured by Changzhou Tronly New Electronic Materials Co., Ltd.), and the like. Examples of a commercially available product include TR-PBG-305, TR-PBG-3057 (all are manufactured by Changzhou Tronly New Electronic Materials Co., Ltd.), and the like.

Examples of the oxime ester-based photopolymerization initiator having a fluorene structure include [(Z)-[3-cyclohexyl-1-(9,9-dibutyl-7-nitrofluoren-2-yl) propylidene] amino) acetate, and the like. Examples of a commercially available product include TR-PBG-358 (manufactured by Changzhou Tronly New Electronic Materials Co., Ltd.), and the like.

The oxime ester-based photopolymerization initiator may be a compound having none of the carbazole structure, the phenyl sulfide structure, and the fluorene structure. Examples of such an oxime ester-based photopolymerization initiator include 1-phenyl-1,2-propane dione-2-o-benzoyl oxime, and the like.

The content of the oxime ester-based photopolymerization initiator is 0.3 parts by mass or more, with respect to a total of 100 parts by mass of the component (A) and the component (B). Accordingly, in both of the mask exposure method and the direct writing method, it is possible to reduce the deviation of the obtained resist line width from the designed value when forming the resist pattern. From the viewpoint of further improving the effect described above, the content of the oxime ester-based photopolymerization initiator may be 0.35 parts by mass or more, or 0.4 parts by mass or more, with respect to a total of 100 parts by mass of the component (A) and the component (B). In addition, from the viewpoint of obtaining a suitable sensitivity, the content of the oxime ester-based photopolymerization initiator may be 3.0 parts by mass or less, 2.5 parts by mass or less, or 2.0 parts by mass or less, with respect to a total of 100 parts by mass of the component (A) and the component (B). From such a viewpoint, the content of the oxime ester-based photopolymerization initiator may be 0.3 to 3.0 parts by mass, 0.35 to 2.5 parts by mass, or 0.4 to 2.0 parts by mass, with respect to a total of 100 parts by mass of the component (A) and the component (B).

The content of the oxime ester-based photopolymerization initiator, from the viewpoint of obtaining a suitable sensitivity, may be in the following range, on the basis of the total mass of the component (C). The content of the oxime ester-based photopolymerization initiator may be 50% by mass or more, 60% by mass or more, 65% by mass or more, 70% by mass or more, or 75% by mass or more. The content of the oxime ester-based photopolymerization initiator may be 100% by mass. That is, the photopolymerization initiator (C) may consist of only the oxime ester-based photopolymerization initiator. From such a viewpoint, the content may be 50 to 100% by mass, 60 to 100% by mass, 65 to 100% by mass, 70 to 100% by mass, or 75 to 100% by mass.

The photosensitive resin composition according to this embodiment may further contain other photopolymerization initiators in addition to the oxime ester-based photopolymerization initiator. Examples of the other photopolymerization initiator include a hexaaryl biimidazole derivative. As the photopolymerization initiator, from the viewpoint of further improving the sensitivity and the adhesiveness, at least one type of 2,4,5-triaryl imidazole dimer is preferable. The structure of the 2,4,5-triaryl imidazole dimer may be symmetric, or may be asymmetric.

Examples of the 2,4,5-triaryl imidazole dimer include a 2-(o-chlorophenyl)-4,5-diphenyl imidazole dimer (also known as 2,2′-bis(o-chlorophenyl)-4,4′,5,5′-tetraphenyl-1,2′-biimidazole), a 2-(o-chlorophenyl)-4,5-bis-(m-methoxyphenyl) imidazole dimer, and a 2-(p-methoxyphenyl)-4,5-diphenyl imidazole dimer. Among them, the 2-(o-chlorophenyl)-4,5-diphenyl imidazole dimer is preferable.

Examples of the other photopolymerization initiator include aromatic ketones such benzophenone, 2-benzyl-2-dimethyl amino-1-(4-morpholinophenyl)-butanone-1,2-(dimethyl amino)-2-[(4-methyl phenyl)methyl]-1-[4-(4-morpholinyl)phenyl]-1-butanone, 4-(2-hydroxyethoxy)phenyl-2-(hydroxy-2-propyl) ketone, and 2-methyl-1-[4-(methyl thio) phenyl]-2-morpholino-propanone-1; quinones such as alkyl anthraquinone; a benzoin ether compound such as benzoin alkyl ether; a benzoin compound such as benzoin and alkyl benzoin; a benzyl derivative such as benzyl dimethyl ketal; bis(2,4,6-trimethyl benzoyl)-phenyl phosphine oxide; bis(2,6-dimethyl benzoyl)-2,4,4-trimethyl-pentyl phosphine oxide; (2,4,6-trimethyl benzoyl) ethoxyphenyl phosphine oxide, and the like.

In a case where the photosensitive resin composition according to this embodiment contains the other photopolymerization initiator described above, the content of the photopolymerization initiator may be 0.01 to 10 parts by mass, 0.01 to 8 parts by mass, or 0.01 to 5 parts by mass, with respect to a total of 100 parts by mass of the component (A) and the component (B).

The content of the component (C), from the viewpoint of further improving the sensitivity and the adhesiveness, may be in the following range, on the basis of the total solid content (the total mass) of the photosensitive resin composition. The content of the component (C) may be 0.1% by mass or more, 0.2% by mass or more, 0.3% by mass or more, or 0.35% by mass or more. The content of the component (C) may be 20% by mass or less, 10% by mass or less, 3% by mass or less, 1% by mass or less, 0.5% by mass or less, or 0.4% by mass or less. From such a viewpoint, the content of the component (C) may be 0.1 to 20% by mass, 0.1 to 10% by mass, or 0.1 to 3% by mass.

### (Component (D): Hydrogen Donor)

The photosensitive resin composition according to this embodiment may further contain a hydrogen donor capable of providing hydrogen during the reaction of an exposed portion. Accordingly, the sensitivity of the photosensitive resin composition is further improved.

Examples of the component (D) include bis [4-(dimethyl amino)phenyl]methane, bis [4-(diethyl amino)phenyl]methane, Leuco crystal violet, and N-phenyl glycine. Only one type of the component (D) can be used alone, or two or more types thereof can be used in combination.

In a case where the photosensitive resin composition according to this embodiment contains the component (D), the content of the component (D) may be in the following range, with respect to 100 parts by mass of the total amount of the component (A) and the component (B). The content of the component (D), from the viewpoint of further improving the sensitivity, may be 0.01 parts by mass or more, 0.05 parts by mass or more, 0.1 parts by mass or more, 0.3 parts by mass or more, 0.5 parts by mass or more, or 0.6 parts by mass or more. The content of the component (D), from the viewpoint of preventing the excessive component (D) from being precipitated as impurities after the film is formed, may be 10 parts by mass or less, 5 parts by mass or less, 2 parts by mass or less, or 1 part by mass or less. From such a viewpoint, the content of the component (D) may be 0.01 to 10 parts by mass, 0.05 to 5 parts by mass, or 0.1 to 2 parts by mass.

### (Sensitizing Dye)

The photosensitive resin composition according to this embodiment may further contain a sensitizing dye. Accordingly, the sensitivity of the photosensitive resin composition is further improved. Examples of the sensitizing dye include dialkyl aminobenzophenones, pyrazolines, anthracenes, coumarins, xanthones, oxazoles, benzoxazoles, thiazoles, benzothiazoles, triazoles, stilbenes, triazines, thiophenes, naphthal imides, and triaryl amines. Only one type of the sensitizing dye can be used alone, or two or more types thereof can be used in combination.

In particular, in a case where a photosensitive resin layer is exposed with an active ray having a wavelength of 390 to 420 nm, the sensitizing dye, from the viewpoint of being more excellent in the sensitivity and the adhesiveness, may include at least one type selected from the group consisting of pyrazolines, anthracenes, coumarins, and triaryl amines, and among them, may include at least one type selected from the group consisting of the pyrazolines, the anthracenes, and the triaryl amines.

In a case where the photosensitive resin composition according to this embodiment contains the sensitizing dye, the content of the sensitizing dye may be 0.01 to 10 parts by mass, 0.05 to 5 parts by mass, or 0.1 to 3 parts by mass, with respect to 100 parts by mass of the total amount of the component (A) and the component (B). By setting the content of the sensitizing dye to be 0.01 parts by mass or more, the sensitivity and the resolution are further improved. By setting the content of the sensitizing dye to be 10 parts by mass or less, the resist shape is prevented from being in the shape of an inverted trapezoid, and the adhesiveness is further improved.

### (Other Components)

The photosensitive resin composition according to this embodiment, as necessary, may contain other components in addition to the components described above. Examples of the other component include a dye (such as malachite green), tribromophenyl sulfone, a photocolor former, a thermal color formation inhibitor, a plasticizer (such as p-toluene sulfone amide), a pigment, a filling agent, an antifoaming agent, a flame retarder, a stabilizer, an adhesiveness imparting agent, a leveling agent, a peeling accelerator, an antioxidant, a fragrance, an imaging agent, and a thermal cross-linking agent. Only one type of the other component can be used alone, or two or more types thereof can be used in combination.

It is preferable that the content of each of the components is approximately 0.01 to 20 parts by mass, with respect to 100 parts by mass of the total amount of the component (A) and the component (B).

The content of the dye such as a dye and a pigment may be less than 0.5% by mass, or may be 0.45% by mass or less, on the basis of the solid content (the total mass) of the photosensitive resin composition.

The photosensitive resin composition according to this embodiment, as necessary, may contain at least one type of organic solvent in order to adjust a viscosity. As the organic solvent, an organic solvent that is commonly used can be used without any particular limitation. Examples of the organic solvent include methanol, ethanol, acetone, methyl ethyl ketone, methyl cellosolve, ethyl cellosolve, toluene, N,N-dimethyl formamide, propylene glycol monomethyl ether, and a mixed solvent thereof.

By dissolving at least the component (A), the component (B), and the component (C) in the organic solvent, the photosensitive resin composition according to this embodiment, for example, can be used as a solution (hereinafter, referred to as a “coating liquid”) with a solid content of approximately 30 to 60% by mass.

The coating liquid, for example, can be used to form the photosensitive resin layer as described below. By applying the coating liquid onto the surface of a support (such as a support film and a metal plate) described below, and drying the coating liquid, the photosensitive resin layer derived from the photosensitive resin composition can be formed on the support. Examples of the metal plate include copper, a copper-based alloy, nickel, chromium, iron, an iron-based alloy (such as stainless steel), and the like, and preferably include the copper, the copper-based alloy, the iron-based alloy, and the like.

The thickness of the photosensitive resin layer varies in accordance with the application thereof, and the thickness after drying may be approximately 1 to 100 μm.

The photosensitive resin composition according to this embodiment, for example, can be preferably used for a method for forming a resist pattern described below. Among them, the photosensitive resin composition is suitable for an application to a method for forming a conductor pattern (a circuit) by a plating treatment.

### <Photosensitive Element>

A photosensitive element according to this embodiment includes a support, and a photosensitive resin layer disposed on the support. The photosensitive resin layer includes the photosensitive resin composition according to this embodiment or the cured product thereof. Note that the photosensitive resin layer is formed by using the photosensitive resin composition according to this embodiment, and the photosensitive resin composition may be in an uncured state (a coated film). The photosensitive element, as necessary, may include other layers such as a protective layer. For example, the surface of the photosensitive resin layer on a side opposite to the surface facing the support may be covered with the protective layer (such as a protective film).

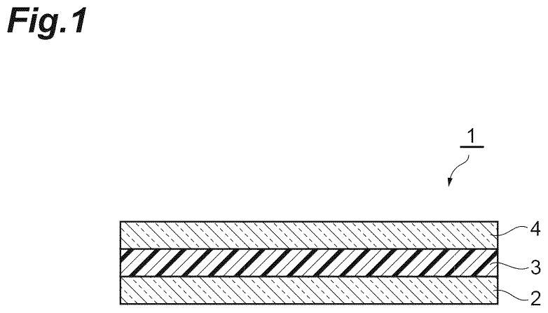

FIG. 1 illustrates one embodiment of the photosensitive element. In a photosensitive element 1 illustrated in FIG. 1, a support 2, a photosensitive resin layer 3, and a protective layer 4 are stacked in this order. The photosensitive element 1, for example, can be obtained as described below. The coating liquid that is the photosensitive resin composition is applied onto the support 2 to form a coated layer, and then, the coated layer is dried to form the photosensitive resin layer 3. Next, the surface of the photosensitive resin layer 3 on a side opposite to the support 2 is covered with the protective layer 4 to obtain the photosensitive element 1 including the support 2, the photosensitive resin layer 3 formed on the support 2, and the protective layer 4 stacked on the photosensitive resin layer 3. The photosensitive element 1 may not necessarily include the protective layer 4.

As the support, a polymer film having heat resistance and solvent resistance, such as a polyethylene terephthalate film, a polyethylene film, a polypropylene film, and a polyester film, can be used.

The thickness of the support (such as the support film) may be 1 to 100 μm, 5 to 50 μm, or 5 to 30 μm. By setting the thickness of the support to be 1 μm or more, it is possible to easily prevent the support from being ruptured when peeling the support. By setting the thickness of the support to be 100 μm or less, it is possible to easily suppress a decrease in the resolution in a case where exposure is performed via the support.

It is preferable that the bonding adhesive force of the protective layer (such as the protective film) with respect to the photosensitive resin layer is less than the bonding adhesive force of the support with respect to the photosensitive resin layer, and a low-fisheye film is preferable. Here, the “fisheye” indicates that when producing a film by thermally fusing, kneading, extruding, biaxially stretching, and casting materials configuring the protective film, the impurities, the undissolved substance, the oxidation deterioration product, and the like of the materials are incorporated into the film. That is, “low fisheye” indicates that there are few impurities in the film.

Specifically, as the protective layer, a polymer film having the heat resistance and the solvent resistance, such as a polyethylene terephthalate film, a polyethylene film, a polypropylene film, and a polyester film, can be used. Examples of a commercially available polymer film include polypropylene films manufactured by Oji Paper Co., Ltd. (for example, Alphan MA-410 and E-200C), manufactured by SHIN-ETSU FILM CO., LTD., and the like; a polyethylene terephthalate film such as PS-25, manufactured by TEIJIN LIMITED (for example, PS Series), and the like. Note that the protective layer may be the same type of member as the support, or may be a different type of member.

The thickness of the protective layer may be 1 to 100 μm, 5 to 50 μm, 5 to 30 μm, or 15 to 30 μm. By setting the thickness of the protective layer to be 1 μm or more, it is possible to prevent the protective layer from being ruptured when laminating the photosensitive resin layer and the support on a base material (such as a substrate) while peeling the protective layer. By setting the thickness of the protective layer to be 100 μm or less, productivity is improved.

The photosensitive element according to this embodiment, for example, can be produced as described below. The photosensitive element can be produced by a production method including a step of dissolving at least the component (A), the component (B), and the component (C) in the organic solvent to prepare the coating liquid with a solid content of approximately 30 to 60% by mass, a step of applying the coating liquid onto the support to form the coated layer, and a step of drying the coated layer to form the photosensitive resin layer.

The coating liquid can be applied onto the support, for example, by a known method such as roll coating, comma coating, gravure coating, air knife coating, die coating, and bar coating. The drying of the coated layer is not particularly limited insofar as at least a part of the organic solvent can be removed from the coated layer. For example, drying may be performed at 70 to 150° C. for approximately 5 to 30 minutes. The amount of remaining organic solvent in the photosensitive resin layer after drying, from the viewpoint of preventing the diffusion of the organic solvent in the subsequent step, may be 2% by mass or less.

The thickness of the photosensitive resin layer in the photosensitive element according to this embodiment can be suitably selected in accordance with the application, and the thickness after drying may be 1 to 100 μm, 1 to 50 μm, or 5 to 40 μm. By setting the thickness of the photosensitive resin layer to be 1 μm or more, industrial coating is facilitated, and the productivity is improved. By setting the thickness of the photosensitive resin layer to be 100 μm or less, the adhesiveness and the resolution are further improved.

The photosensitive element according to this embodiment, as necessary, may further include a known intermediate layer such as a cushion layer, a bonding adhesive layer, a light absorption layer, a gas barrier layer, and the like.

The form of the photosensitive element according to this embodiment is not particularly limited. The photosensitive element, for example, may be in the shape of a sheet, or may be in a state of being wound around a winding stem into the shape of a roll.

The photosensitive element according to this embodiment, for example, can be preferably used for a method for forming a resist pattern described below. Among them, the photosensitive element is suitable for an application to the method for forming the conductor pattern (the circuit) by the plating treatment.

### <Method for Forming Resist Pattern>

A method for forming a resist pattern according to this embodiment includes (i) a step of forming a photosensitive resin layer on a base material (such as a substrate) by using the photosensitive resin composition or the photosensitive element (a photosensitive resin layer forming step), (ii) a step of irradiating at least a part of the photosensitive resin layer with an active ray to cure the photosensitive resin layer (an exposing step), and (iii) a step of removing an uncured portion of the photosensitive resin layer from the base material to form a resist pattern (a developing step), and as necessary, includes other steps. Note that the resist pattern can also be referred to as a relief pattern. The method for forming a resist pattern according to this embodiment can also be referred to as a method for producing a base material with a resist pattern.

### ((i) Photosensitive Resin Layer Forming Step)

In the photosensitive resin layer forming step, the photosensitive resin layer is formed on the base material (such as the substrate) by using the photosensitive resin composition or the photosensitive element. The base material is not particularly limited, and examples thereof include a base material including a conductor layer. As the base material including the conductor layer, a substrate for forming a circuit including an insulating layer, and a conductor layer formed on the insulating layer, or a die pad (such as a base material for a lead frame and an alloy base material) can be used.

Examples of a method for forming the photosensitive resin layer on the base material (such as the substrate) include a method for removing the protective layer from the photosensitive element, and then, crimping the photosensitive resin layer of the photosensitive element to the base material while heating the photosensitive resin layer. Accordingly, a stacked body consisting of the base material, the photosensitive resin layer, and the support is obtained, in which the base material, the photosensitive resin layer, and the support are stacked in this order. In addition, the photosensitive resin layer may be formed by applying and drying the photosensitive resin composition.

From the viewpoint of being more excellent in the adhesiveness and followability, it is preferable that the photosensitive resin layer forming step is performed under a reduced pressure. The heating of the photosensitive resin layer and/or the base material (such as the substrate) during crimping may be performed at a temperature of 70 to 130° C. The crimping may be performed at a pressure of approximately 0.1 to 1.0 MPa (approximately 1 to 10 kgf/cm²). Such a condition, as necessary, can be suitably selected. Note that in a case where the photosensitive resin layer is heated to 70 to 130° C., it is not necessary to perform in advance a preheat treatment on the base material, but in order to further improve the adhesiveness and the followability, the preheat treatment can also be performed on the base material.

((ii) Exposing Step)

In the exposing step, by irradiating at least a part of the photosensitive resin layer formed on the base material (such as the substrate) with the active ray, a portion irradiated with the active ray is cured to form a latent image.

In a case where the support on the photosensitive resin layer has transmissiveness with respect to the active ray, the active ray can be applied via the support. In a case where the support has a light blocking property, the photosensitive resin layer can be irradiated with the active ray after removing the support.

As an exposure method, a method for applying an active ray into the shape of an image by a direct writing exposure method such as a laser direct imaging (LDI) exposure method and a digital light processing (DLP) exposure method may be adopted, a method (a mask exposure method) for applying an active ray into the shape of an image via a negative or positive mask pattern, referred to as artwork, may be adopted, or both of the methods may be used together.

As a light source of the active ray, a known light source can be used. For example, a light source for effectively emitting an ultraviolet ray or visible light, such as a carbon arc lamp, a mercury vapor arc lamp, a high-pressure mercury lamp, a xenon lamp, gas laser (such as argon laser), solid-state laser (such as YAG laser), and semiconductor laser, can be used. Examples of the main wavelength of the active ray include 355 nm, 405 nm, and the like. The main wavelength indicates the set wavelength of the active ray, and for example, light having a main wavelength of 355 nm may include light having a wavelength of 352 to 358 nm.

((iii) Developing Step)

In the developing step, by removing the uncured portion of the photosensitive resin layer from the base material (such as the substrate), the resist pattern consisting of the cured product obtained by photocuring the photosensitive resin layer is formed on the base material. In a case where the support is on the photosensitive resin layer, the support is removed, and then, an unexposed portion other than an exposed portion is removed (developed). Examples of a development method include wet development and dry development, and the wet development is widely used.

In the case of using the wet development, development can be performed by a known development method using a developer corresponding to the photosensitive resin composition. Examples of the development method include a dipping method, a puddle method, a spray method, a method using brushing, slapping, scrubbing, or fluctuating immersion, and the like, and from the viewpoint of further improving the resolution, a high-pressure spray method is most suitable. The development may be performed by combining two or more types of development methods.

The configuration of the developer is suitably selected in accordance with the configuration of the photosensitive resin composition. Examples of the developer include an alkaline aqueous solution and an organic solvent developer.

In a case where the alkaline aqueous solution is used as the developer, it is safe and stable, and excellent in manipulativeness. As the base of the alkaline aqueous solution, alkali hydroxide such as a hydroxide of lithium, sodium, or potassium; alkali carbonate such as a carbonate or a bicarbonate of lithium, sodium, potassium, or ammonium; an alkali metallic phosphate such as potassium phosphate and sodium phosphate; an alkali metallic pyrophosphate such as sodium pyrophosphate and potassium pyrophosphate; borax; sodium metasilicate; tetramethyl ammonium hydroxide; ethanol amine; ethylene diamine; diethylene triamine; 2-amino-2-hydroxymethyl-1,3-propane diol; 1,3-diamino-2-propanol; morpholine, and the like.

As the alkaline aqueous solution, a diluted solution with 0.1 to 5% by mass of sodium carbonate, a diluted solution with 0.1 to 5% by mass of potassium carbonate, a diluted solution with 0.1 to 5% by mass of sodium hydroxide, a diluted solution with 0.1 to 5% by mass of sodium tetraborate, and the like are preferable. It is preferable that the pH of the alkaline aqueous solution is 9 to 11. The temperature of the alkaline aqueous solution is adjusted in accordance with the alkali developing property of the photosensitive resin layer. In the alkaline aqueous solution, a surface-active agent, an antifoaming agent, a small amount of organic solvent for accelerating development, and the like may be mixed.

Examples of the organic solvent include acetone, ethyl acetate, alkoxyethanol having an alkoxy group having 1 to 4 carbon atoms, ethyl alcohol, isopropyl alcohol, butyl alcohol, diethylene glycol monomethyl ether, diethylene glycol monoethyl ether, diethylene glycol monobutyl ether, and the like. Only one type of the organic solvent can be used alone, or two or more types thereof can be used in combination. It is preferable that the content of the organic solvent in a water-based developer is generally 2 to 90% by mass, and the temperature thereof can be adjusted in accordance with the alkali developing property.

Examples of the organic solvent developer include an organic solvent such as 1,1,1-trichloroethane, N-methyl pyrrolidone, N,N-dimethyl formamide, cyclohexanone, methyl isobutyl ketone, and γ-butyrolactone. In order to prevent ignition, it is preferable to add water in a range of 1 to 20% by mass to the organic solvent.

In this embodiment, the unexposed portion is removed in the developing step, and then, as necessary, heating at approximately 60 to 250° C. or exposure at approximately 0.2 to 10 J/cm² may be performed to further cure the resist pattern.

### <Method for Producing Printed Circuit Board>

A method for producing a printed circuit board according to this embodiment includes a step of forming a resist pattern on a base material (such as a substrate) by the method for forming a resist pattern, and a step of performing a plating treatment or an etching treatment on a member having the base material (such as the substrate) and the resist pattern (the base material on which the resist pattern is formed, or the base material with the resist pattern) to form a conductor pattern. In addition, the method for producing a printed circuit board according to this embodiment, as necessary, may include other steps such as a step of removing the resist pattern.

In this embodiment, for example, the base material (for example, a conductor layer provided on the base material) can be subjected to the plating treatment or the etching treatment by using the resist pattern on the base material (such as the substrate) as a mask.

A plating treatment method in the method for producing a printed circuit board may be one or both of an electrolytic plating treatment and an electroless plating treatment, and it is preferable to perform the electroless plating treatment. Examples of the electroless plating treatment include copper plating such as copper sulfate plating and copper pyrophosphate plating; solder plating such as high throw solder plating; Watts bath (nickel sulfate-nickel chloride) plating; nickel plating such as nickel sulfamate; gold plating, and the like.

In the step of removing the resist pattern, for example, the resist pattern can be peeled with an alkaline aqueous solution stronger than the alkaline aqueous solution used in the developing step. Examples of such a strong alkaline aqueous solution include 1 to 10% by mass of a sodium hydroxide aqueous solution, 1 to 10% by mass of a potassium hydroxide aqueous solution, and the like. Examples of a method for removing the resist pattern include an immersion method, a spray method, and the like, and such methods may be used alone, or may be used together.

An etching treatment method can be suitably selected in accordance with the conductor layer (a metal layer) to be removed. Examples of an etching liquid include a copper (II) chloride solution, an iron (II) chloride solution, an alkali etching solution, and a hydrogen peroxide etching liquid. Among them, from the viewpoint of an excellent etching factor, it is preferable to use the iron (II) chloride solution.

A printed circuit board produced by the method for producing a printed circuit board according to this embodiment may be a multilayer printed circuit board, and may have a through hole with a small diameter.

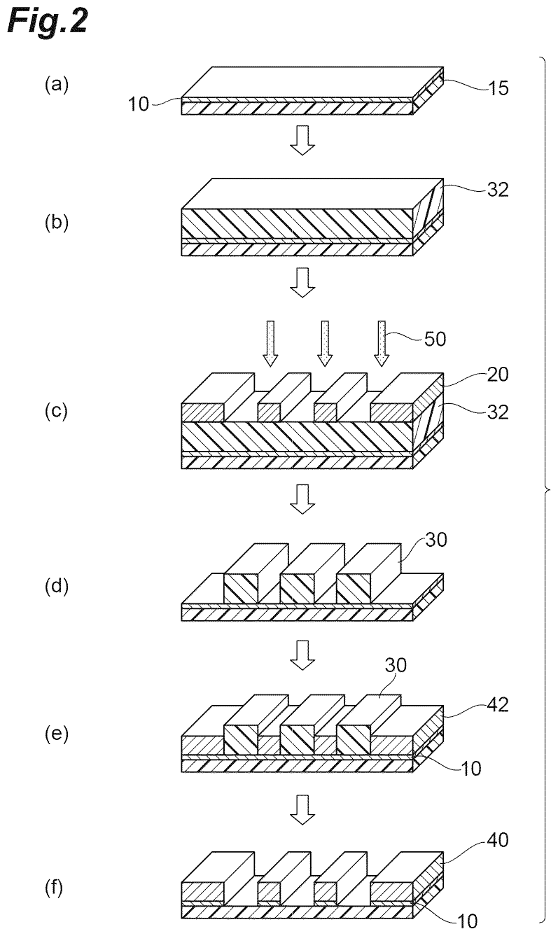

A printed circuit board according to this embodiment can be produced by a production method including a step of performing an etching treatment or an etching treatment on the base material on which the resist pattern is formed by the method for forming a resist pattern according to this embodiment to form a conductor pattern. Hereinafter, an example of a step of producing a printed circuit board by a semi-additive method will be described with reference to FIG. 2.

In FIG. 2(a), a substrate (a substrate for forming a circuit) in which a conductor layer 10 is formed on an insulating layer 15 is prepared. The conductor layer 10, for example, is a copper metal layer. In FIG. 2(b), by the photosensitive resin layer forming step, a photosensitive resin layer 32 is formed on the conductor layer 10 of the substrate. In FIG. 2(c), a mask 20 is disposed on the photosensitive resin layer 32, and an active ray 50 is applied to expose a region other than a region where the mask 20 is disposed such that a photocured portion is formed. In FIG. 2(d), the region other than the photocured portion formed by the exposing step is removed from the substrate by the developing step to form a resist pattern 30, which is the photocured portion, on the substrate. In FIG. 2(e), by a plating treatment using the resist pattern 30, which is the photocured portion, as a mask, a plating layer 42 is formed on the conductor layer 10. In FIG. 2(f), the resist pattern 30, which is the photocured portion, is peeled with a strong alkaline aqueous solution, and then, a part of the plating layer 42, and the conductor layer 10 masked by the resist pattern 30 are removed by a flash etching treatment to form a conductor pattern 40. The conductor layer 10 and the plating layer 42 may contain the same material, or may contain different materials. In a case where the conductor layer 10 and the plating layer 42 contain the same material, the conductor layer 10 and the plating layer 42 may be integrated. Note that a method for forming the resist pattern 30 by using the mask 20 is described in FIG. 2, but the resist pattern 30 may be formed by a direct writing exposure method without using the mask 20.

### EXAMPLES

Hereinafter, the present disclosure will be described in more detail by Examples. However, the present disclosure is not limited to such Examples.

### Examples 1 to 7 and Comparative Examples 1 to 6

### <Production of Photosensitive Resin Composition>

Each material shown in Table 1 and Table 2 was mixed in a blending amount (Unit: parts by mass) shown in the same table to produce a solution of a photosensitive resin composition. Note that the blending amount (parts by mass) of a component other than a solvent shown in Table 1 and Table 2 is the mass of a non-volatile content (a solid content). The details of each component shown in Table 1 and Table 2 are as follows.

### (Binder Polymer (A))

A-1: a propylene glycol monomethyl ether/toluene (a mass ratio of ¾) solution (Solid Content:49.6% by mass) of a copolymer of methacrylic acid/styrene/benzyl methacrylate/2-hydroxyethyl methacrylate (Mass Ratio: 27/50/20/3, Mw: 35000, Acid Value: 176.1 mgKOH/g, Tg: 106.8° C.)
A-2: a propylene glycol monomethyl ether/toluene (a mass ratio of ¾) solution (Solid Content:47% by mass) of a copolymer of methacrylic acid/methyl methacrylate/styrene/benzyl methacrylate (Mass Ratio:27/5/45/23, Mw:51000, Acid Value: 176.1 mgKOH/g, Tg: 107.0° C.)

### (Photopolymerizable Compound (B))

FA-321M: 2,2-bis(4-(methacryloxypentaethoxy)phenyl) propane (manufactured by Resonac Corporation., Number of EO Groups: 10 (the average value))
BP-2EM: 2,2-bis(4-(methacryloxypolyethoxy)phenyl) propane (EO Group: 2.6 (the total value), manufactured by Kyoeisha Chemical Co., Ltd.)
BPE-200:2,2-bis(4-(methacryloxydiethoxy)phenyl) propane (manufactured by SHIN-NAKAMURA CHEMICAL CO., LTD.)
FA-024M: polyalkylene glycol dimethacrylate (manufactured by Resonac Corporation., Number of EO Groups: 12 (the average value), Number of PO Groups: 6 (the average value))
FA-023M: polyalkylene glycol dimethacrylate (manufactured by Resonac Corporation., Number of EO Groups: 6 (the average value), Number of PO Groups: 12 (the average value))
FA-MECH: γ-chloro-β-hydroxypropyl-β′-methacryloyl oxyethyl-o-phthalate (manufactured by Resonac Corporation.)

### (Photopolymerization Initiator (C))

B-CIM: 2,2′-bis(2-chlorophenyl)-4,4′,5,5′-tetraphenyl biimidazole (manufactured by Changzhou Tronly New Electronic Materials Co., Ltd.)
TR-PBG-304: an oxime ester-based photopolymerization initiator (manufactured by Changzhou Tronly New Electronic Materials Co., Ltd.) having a carbazole structure represented by Formula (1) described below

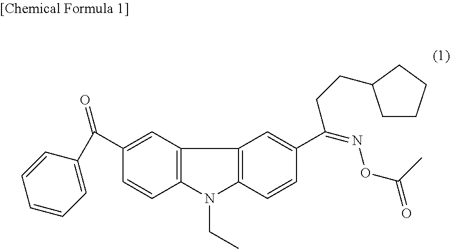 [SMILES: CCn1c2ccc(C(=O)c3ccccc3)cc2c2cc(/C(CCC3CCCC3)=N\OC(C)=O)ccc21]

TR-PBG-305: an oxime ester-based photopolymerization initiator (manufactured by Changzhou Tronly New Electronic Materials Co., Ltd.) having a phenyl sulfide structure represented by Formula (2) described below

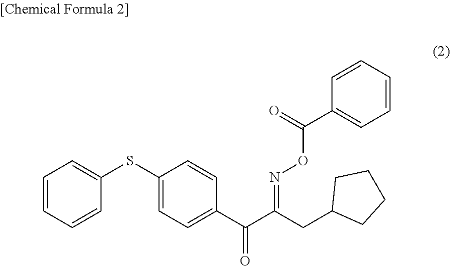 [SMILES: O=C(O/N=C(\CC1CCCC1)C(=O)c1ccc(Sc2ccccc2)cc1)c1ccccc1]

TR-PBG-314: an oxime ester-based photopolymerization initiator (manufactured by Changzhou Tronly New Electronic Materials Co., Ltd.) having a carbazole structure represented by Formula (3) described below

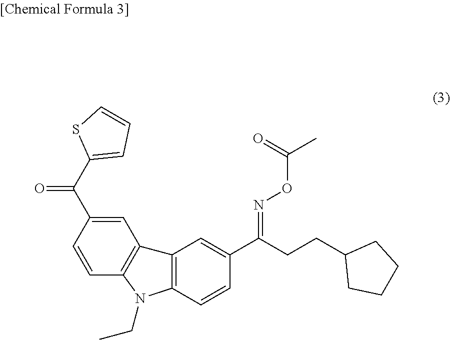 [SMILES: CCn1c2ccc(C(=O)c3cccs3)cc2c2cc(/C(CCC3CCCC3)=N/OC(C)=O)ccc21]

TR-PBG-345: an oxime ester-based photopolymerization initiator (manufactured by Changzhou Tronly New Electronic Materials Co., Ltd.) having a carbazole structure represented by Formula (4) described below

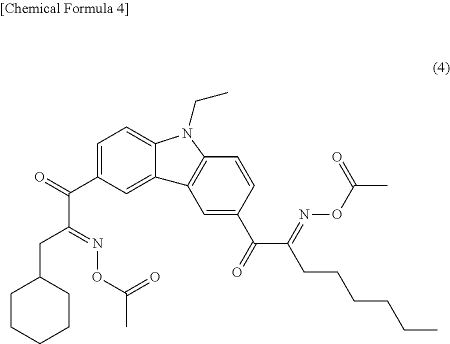 [SMILES: CCCCCC/C(=N\OC(C)=O)C(=O)c1ccc2c(c1)c1cc(C(=O)/C(CC3CCCCC3)=N/OC(C)=O)ccc1n2CC]

TR-PBG-358: an oxime ester-based photopolymerization initiator (manufactured by Changzhou Tronly New Electronic Materials Co., Ltd.) having a fluorene structure represented by Formula (5) described below

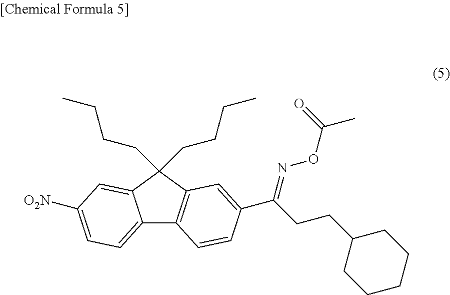 [SMILES: CCCCC1(CCCC)c2cc(/C(CCC3CCCCC3)=N/OC(C)=O)ccc2-c2ccc([N+](=O)[O-])cc21]

TR-PBG-365: an oxime ester-based photopolymerization initiator (manufactured by Changzhou Tronly New Electronic Materials Co., Ltd.) having a fluorene structure
TR-PBG-3057: an oxime ester-based photopolymerization initiator (manufactured by Changzhou Tronly New Electronic Materials Co., Ltd.) having a phenyl sulfide structure represented by Formula (6) described below

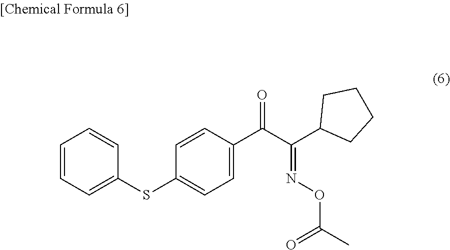 [SMILES: CC(=O)O/N=C(/C(=O)c1ccc(Sc2ccccc2)cc1)C1CCCC1]

### (Other Components)

DBA: 9,10-dibutoxyanthracene (manufactured by KAWASAKI KASEI CHEMICALS LTD.)
TBC: 4-tert-butyl catechol (manufactured by DIC Corporation) (a polymerization inhibitor)
LCV: Leuco crystal violet (manufactured by Yamada Chemical Co. Ltd.) (a color former)
MKG: malachite green (manufactured by OSAKA ORGANIC CHEMICAL INDUSTRY LTD.) (a dye)
LA-7RD: 4-hydroxy-2,2,6,6-tetramethyl piperidine-N-oxyl (manufactured by ADEKA CORPORATION)
FA-711 MM: 1,2,2,6,6-pentamethyl piperidin-4-yl methacrylate (manufactured by Resonac Corporation.)
SF-808H: a mixture of carboxybenzotriazole, 5-amino-1H-tetrazole, and methoxypropanol (manufactured by Sanwa Kasei Kogyo Co., Ltd.)

### <Production of Photosensitive Element>

Each of the photosensitive resin compositions obtained as described above was applied onto a polyethylene terephthalate film (manufactured by TORAY INDUSTRIES, INC., Product Name “FS-31”, a support) with a thickness of 16 μm to have an even thickness. Next, drying was performed with a hot-air convection dryer at 80° C. and 120° C. to form a photosensitive resin layer of which the thickness after drying was 25 μm. By sticking a polyethylene film (manufactured by Tamapoly CO., LTD., Product Name “NF-15”) (a protective layer) onto the photosensitive resin layer, each photosensitive element was obtained in which the support, the photosensitive resin layer, and the protective layer were stacked in this order.

### <Production of Stacked Body>

A copper clad laminate (a substrate, manufactured by Resonac Corporation., Product Name “MLC-E-67”), which is a glass epoxy material in which a copper foil (Thickness: 35 μm) is stacked on both surfaces, was washed with water, washed with an acid, and washed with water in this order, and then, dried with an air flow. The copper clad laminate was heated to 80° C. Each of the photosensitive elements obtained as described above was laminated such that the photosensitive resin layer was in contact with the copper surface while peeling the protective layer. Accordingly, each stacked body was obtained in which the copper clad laminate, the photosensitive resin layer, and the support were stacked in this order. The obtained stacked body was used as a test piece in an accuracy evaluation test of a resist line width described below. Note that the lamination was performed at a crimping pressure of 0.4 MPa and a roll rate of 1.0 m/minute by using a heat roll at 110° C.

### <Measurement of Shortest Developing Time>

The stacked body described above was cut into the shape of a square (5 cm×5 cm), and then, the support was peeled to obtain a test piece. Next, by using 1% by mass of a sodium carbonate aqueous solution at 30° C., the unexposed photosensitive resin layer in the test piece was subjected to spray development (Nozzle: a full cone type, Distance between Treatment Target and Nozzle Tip: 6 cm) at a pressure of 0.18 MPa, and the shortest time required to enable the removal of the unexposed photosensitive resin layer to be visually checked was obtained as the shortest developing time (MD).

### <Accuracy Evaluation of Resist Line Width (Mask Exposure Method)>

A 41-stage step tablet (manufactured by Resonac Corporation.) and a photomask (a photomask with missing lines having a line width of 10 μm) were placed on the support of the test piece. By using a parallel exposure machine (manufactured by ORC MANUFACTURING CO., LTD., Product Name: EXM1201), an ultraviolet ray was applied from a direction perpendicularly above the surface of the photomask in an energy amount at which the number of remaining steps of the 41-stage step tablet was 15. After that, the support was peeled, and spray development was performed for a time period twice the shortest developing time obtained by the method described above to remove an unexposed portion. Accordingly, a resist pattern, which is a photocured product of the photosensitive resin composition, was formed on the copper clad laminate. The line width of the obtained resist pattern was measured at three spots, the average value thereof was set as the actually measured value (Unit: μm) of the line width, and a ratio (actually measured value/designed value) of the actually measured value to the designed value (10 μm) of the line width of the photomask was obtained. The value of the ratio (actually measured value/designed value) is shown in Table 1 and Table 2 as the accuracy of the resist line width. As the value is close to 1, the deviation of the obtained resist line width from the designed value is small.

TABLE 1

| Component | | Example 1 | Example 2 | Example 3 | Example 4 | Example 5 | Example 6 | Example 7 |
|---|---|---|---|---|---|---|---|---|
| Component | A-1 | 56 | 56 | 56 | 56 | 56 | 56 | 56 |
| (A) | | | | | | | | |
| Component | FA-321M | 44 | 44 | 44 | 44 | 44 | 44 | 44 |
| (B) | | | | | | | | |
| Component | TR-PBG-304 | 0.480 | — | — | — | — | — | — |
| (C) | TR-PBG-305 | — | 0.434 | — | — | — | — | — |
| | TR-PBG-314 | — | — | 0.476 | — | — | — | — |
| | TR-PBG-345 | — | — | — | 0.588 | — | — | — |
| | TR-PBG-358 | — | — | — | — | 0.507 | — | — |
| | TR-PBG-365 | — | — | — | — | — | 0.477 | — |
| | TR-PBG-3057 | — | — | — | — | — | — | 0.387 |
| Others | DBA | 0.65 | 0.65 | — | — | — | 0.65 | 0.65 |
| | TBC | 0.02 | 0.02 | 0.02 | 0.02 | 0.02 | 0.02 | 0.02 |
| | LCV | 0.4 | 0.4 | 0.4 | 0.4 | 0.4 | 0.4 | 0.4 |
| | MKG | 0.02 | 0.02 | 0.02 | 0.02 | 0.02 | 0.02 | 0.02 |
| | LA-7RD | 0.03 | 0.03 | 0.03 | 0.03 | 0.03 | 0.03 | 0.03 |
| | SF-808H | 0.5 | 0.5 | 0.5 | 0.5 | 0.5 | 0.5 | 0.5 |
| Solvent | Acetone | 10 | 10 | 10 | 10 | 10 | 10 | 10 |
| | Toluene | 16 | 16 | 16 | 16 | 16 | 16 | 16 |
| | Methanol | 6 | 6 | 6 | 6 | 6 | 6 | 6 |

| | | | | | | | |
|---|---|---|---|---|---|---|---|
| Accuracy of line width | 0.94 | 0.90 | 1.00 | 1.06 | 0.96 | 0.93 | 0.92 |

TABLE 2

| | | Comparative | Comparative | Comparative | Comparative | Comparative | Comparative |
|---|---|---|---|---|---|---|---|
| Component | | Example 1 | Example 2 | Example 3 | Example 4 | Example 5 | Example 6 |
| Component | A-1 | 56 | 56 | — | — | 56 | 56 |
| (A) | A-2 | — | — | 55 | 58 | — | — |
| Component | FA-321M | 44 | 35 | 33 | 27 | 44 | 44 |
| (B) | BP-2EM | — | 5 | — | — | — | — |
| | BPE-200 | — | — | 7 | — | — | — |
| | FA-024M | — | 4 | 5 | — | — | — |
| | FA-023M | — | — | — | 10 | — | — |
| | FA-MECH | — | — | — | 5 | — | — |
| Component | B-CIM | 6.5 | 6.0 | 4.5 | 3.7 | — | — |
| (C) | TR-PBG-304 | — | — | — | — | 0.048 | 0.250 |
| Others | DBA | 0.65 | 0.65 | 0.65 | 0.65 | — | — |
| | TBC | 0.02 | 0.015 | 0.005 | 0.005 | 0.02 | 0.02 |
| | LCV | 0.4 | 0.5 | 0.5 | 0.5 | 0.4 | 0.4 |
| | MKG | 0.02 | 0.02 | 0.03 | 0.03 | 0.02 | 0.02 |
| | LA-7RD | 0.03 | 0.01 | — | — | 0.03 | 0.03 |
| | FA-711MM | — | 1 | 1 | — | — | — |
| | SF-808H | 0.5 | 0.5 | 1 | 0.2 | 0.5 | — |
| Solvent | Acetone | 10 | 10 | 10 | 5 | 10 | 10 |
| | Toluene | 16 | 16 | 10 | 9 | 16 | 16 |
| | Methanol | 6 | 6 | 6 | 5 | 6 | 6 |

| | | | | | | |
|---|---|---|---|---|---|---|
| Accuracy of line width | 1.18 | 1.16 | 1.17 | 1.55 | 0.60 | 0.76 |

### Examples 8 to 12 and Comparative Examples 7 to 10

### <Production of Photosensitive Resin Composition>

Each material shown in Table 3 was mixed in a blending amount (Unit: parts by mass) shown in the same table to produce a solution of a photosensitive resin composition. Note that the blending amount (parts by mass) of a component other than a solvent shown in Table 3 is the mass of a non-volatile content (a solid content). The details of each component shown in Table 3 are as follows. Here, the details of the same components as the components shown in Table 1 and Table 2 are as described above.

### (Binder Polymer (A))

A-3: an acetone/propylene glycol monomethyl ether (a mass ratio of 6/1) solution (Solid Content:47% by mass) of a copolymer of methacrylic acid/methyl methacrylate/styrene/benzyl methacrylate (Mass Ratio: 27/5/45/23, Mw: 47000, Acid Value: 176.1 mgKOH/g, Tg:107.0° C.)

### (Photopolymerization Initiator (C))

C-1: an oxime ester-based photopolymerization initiator (manufactured by Nippon Chemical Laboratory Co., Ltd.) having a carbazole structure represented by Formula (7) described below

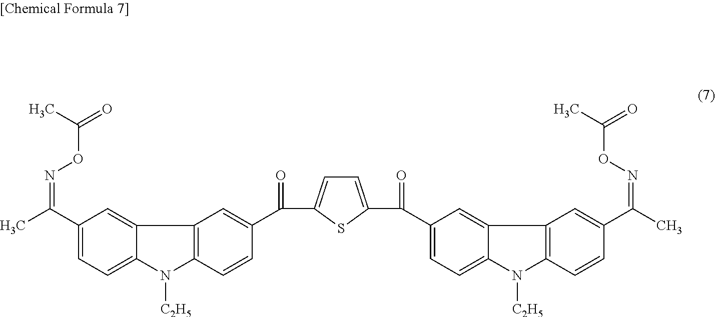 [SMILES: CCn1c2ccc(C(=O)c3ccc(C(=O)c4ccc5c(c4)c4cc(/C(C)=N\OC(C)=O)ccc4n5CC)s3)cc2c2cc(/C(C)=N\OC(C)=O)ccc21]

### <Production of Photosensitive Element>

Each of the photosensitive resin compositions obtained as described above was applied onto a polyethylene terephthalate film (manufactured by TORAY INDUSTRIES, INC., Product Name “FS-31”, a support) with a thickness of 16 μm to have an even thickness. Next, drying was performed with a hot-air convection dryer at 80° C. and 120° C. to form a photosensitive resin layer of which the thickness after drying was 25 μm. By sticking a polyethylene film (manufactured by Tamapoly CO., LTD., Product Name “NF-15”) (a protective layer) onto the photosensitive resin layer, each photosensitive element was obtained in which the support, the photosensitive resin layer, and the protective layer were stacked in this order.

### <Production of Stacked Body>

A copper clad laminate (a substrate, manufactured by Resonac Corporation., Product Name “MLC-E-679”), which is a glass epoxy material in which a copper foil (Thickness: 35 μm) is stacked on both surfaces, was washed with water, washed with an acid, and washed with water in this order, and then, dried with an air flow. The copper clad laminate was heated to 80° C. Each of the photosensitive elements obtained as described above was laminated such that the photosensitive resin layer was in contact with the copper surface while peeling the protective layer. Accordingly, each stacked body was obtained in which the copper clad laminate, the photosensitive resin layer, and the support were stacked in this order. The obtained stacked body was used as a test piece in an accuracy evaluation test of a resist line width described below. Note that the lamination was performed at a crimping pressure of 0.4 MPa and a roll rate of 1.0 m/minute by using a heat roll at 110° C.

### <Accuracy Evaluation of Resist Line Width (Direct Writing Method)>

A 41-stage step tablet (manufactured by Resonac Corporation.) was placed on the support of the test piece. Next, by using an LDI exposure machine (a main wavelength of 405 nm, manufactured by ADTEC Engineering Co., Ltd., Product Name “DE-1UH”), exposure was performed in an energy amount at which the number of remaining steps of the 41-stage step tablet was 15. Next, the support was peeled, and spray development was performed for a time period twice the shortest developing time obtained by the method described above to remove an unexposed portion. Accordingly, a resist pattern (Designed Value of Line Width: 10 μm), which is a photocured product of the photosensitive resin composition, was formed on the copper clad laminate. The line width of the obtained resist pattern was measured at three spots, the average value was set as the actually measured value (Unit: μm) of the line width, and a ratio (actually measured value/designed value) of the actually measured value to the designed value (10 μm) of the line width of the photomask was obtained. The value of the ratio (actually measured value/designed value) is shown in Table 3 as the accuracy of the resist line width. As the value is close to 1, the deviation of the obtained resist line width from the designed value is small.

TABLE 3

| | | Ex- | Ex- | Ex- | Ex- | Ex- | Comparative | Comparative | Comparative | Comparative |
|---|---|---|---|---|---|---|---|---|---|---|
| Component | | ample 8 | ample 9 | ample 10 | ample 11 | ample 12 | Example 7 | Example 8 | Example 9 | Example 10 |
| Component | A-1 | 56 | 56 | 56 | 56 | 56 | 56 | — | — | 56 |
| (A) | A-2 | — | — | — | — | — | — | 55 | — | — |
| | A-3 | — | — | — | — | — | — | — | 58 | — |
| Component | FA-321M | 35 | 35 | 35 | 35 | 35 | 35 | 33 | 27 | 35 |
| (B) | BP-2EM | 5 | 5 | 5 | 5 | 5 | 5 | — | — | 5 |
| | BPE-200 | — | — | — | — | — | — | 7 | — | — |
| | FA-024M | 4 | 4 | 4 | 4 | 4 | 4 | 5 | — | 4 |
| | FA-023M | — | — | — | — | — | — | — | 10 | — |
| | FA-MECH | — | — | — | — | — | — | — | 5 | — |
| Component | B-CIM | — | — | — | — | — | 6.0 | 4.5 | 3.7 | 3.0 |
| (C) | C-1 | 0.500 | — | — | — | — | — | — | — | — |
| | TR-PBG-345 | — | 0.588 | 1.764 | — | 2.940 | — | — | — | — |
| | TR-PBG-358 | — | — | — | 1.514 | — | — | — | — | — |
| Others | DBA | — | — | — | — | — | 0.65 | 0.65 | 0.65 | 0.65 |
| | TBC | 0.015 | 0.015 | 0.015 | 0.015 | 0.015 | 0.015 | 0.005 | 0.005 | 0.015 |
| | LCV | 0.5 | 0.5 | 0.5 | 0.5 | 0.5 | 0.5 | 0.5 | 0.5 | 0.5 |
| | MKG | 0.02 | 0.02 | 0.02 | 0.02 | 0.02 | 0.02 | 0.03 | 0.03 | 0.02 |
| | LA-7RD | 0.01 | 0.01 | 0.01 | 0.01 | 0.01 | 0.01 | — | — | 0.01 |
| | FA-711MM | 1 | 1 | 1 | 1 | 1 | 1 | 1 | — | 1 |
| | SF-808H | 0.5 | 0.5 | 0.5 | 0.5 | 0.5 | 0.5 | 1 | 0.2 | 0.5 |
| Solvent | Acetone | 10 | 10 | 10 | 10 | 10 | 10 | 10 | 5 | 10 |
| | Toluene | 16 | 16 | 16 | 16 | 16 | 16 | 10 | 9 | 16 |
| | Methanol | 6 | 6 | 6 | 6 | 6 | 6 | 6 | 5 | 6 |

| | | | | | | | | | |
|---|---|---|---|---|---|---|---|---|---|
| Accuracy of line width | 0.94 | 0.86 | 0.90 | 0.91 | 0.88 | 1.58 | 1.39 | 2.06 | 1.19 |

### REFERENCE SIGNS LIST

1: photosensitive element, 2: support, 3, 32: photosensitive resin layer, 4: protective layer, 10: conductor layer, 15: insulating layer, 20: mask, 30: resist pattern, 40: conductor pattern, 42: plating layer, 50: active ray.

1. A photosensitive resin composition, comprising:
a binder polymer (A);
a photopolymerizable compound (B) having at least one ethylenically unsaturated bond; and
a photopolymerization initiator (C),
wherein the photopolymerization initiator (C) includes an oxime ester-based photopolymerization initiator, and
a content of the oxime ester-based photopolymerization initiator is 0.3 parts by mass or more, with respect to a total of 100 parts by mass of the binder polymer (A) and the photopolymerizable compound (B).

2. The photosensitive resin composition according to claim 1,
wherein the binder polymer (A) has a structural unit derived from a (meth)acrylic acid, and a structural unit derived from benzyl (meth)acrylate or a benzyl (meth)acrylate derivative.

3. The photosensitive resin composition according to claim 1,
wherein the photopolymerization initiator (C) consists of only the oxime ester-based photopolymerization initiator.

4. The photosensitive resin composition according to claim 1,
wherein the oxime ester-based photopolymerization initiator includes a compound having a carbazole structure.

5. The photosensitive resin composition according to claim 1,
wherein the oxime ester-based photopolymerization initiator includes a compound having a phenyl sulfide structure.

6. The photosensitive resin composition according to claim 1,
wherein the oxime ester-based photopolymerization initiator includes a compound having a fluorene structure.

7. The photosensitive resin composition according to claim 1,
wherein the content of the oxime ester-based photopolymerization initiator is 3.0 parts by mass or less, with respect to a total of 100 parts by mass of the binder polymer (A) and the photopolymerizable compound (B).

8. The photosensitive resin composition according to claim 1,
wherein the photosensitive resin composition is used for a direct writing method.

9. A photosensitive element, comprising:
a support; and
a photosensitive resin layer disposed on the support,
wherein the photosensitive resin layer includes the photosensitive resin composition according to claim 1.

10. A cured product of the photosensitive resin composition according to claim 1.

11. The cured product according to claim 10,
wherein the cured product is a resist pattern.

12. A method for forming a resist pattern, comprising:
a step of forming a photosensitive resin layer on a base material by using the photosensitive resin composition according to claim 1;
a step of irradiating at least a part of the photosensitive resin layer with an active ray to cure the photosensitive resin layer; and
a step of removing an uncured portion of the photosensitive resin layer from the base material to form a resist pattern.

13. A method for forming a resist pattern, comprising:
a step of forming a photosensitive resin layer on a base material by using the photosensitive element according to claim 9;
a step of irradiating at least a part of the photosensitive resin layer with an active ray to cure the photosensitive resin layer; and
a step of removing an uncured portion of the photosensitive resin layer from the base material to form a resist pattern.

14. A method for producing a printed circuit board, comprising:
a step of forming a resist pattern on the base material by the method for forming a resist pattern according to claim 12; and
a step of performing a plating treatment or an etching treatment on a member having the base material and the resist pattern.

15. A method for producing a printed circuit board, comprising:
a step of forming a resist pattern on the base material by the method for forming a resist pattern according to claim 13; and
a step of performing a plating treatment or an etching treatment on a member having the base material and the resist pattern.
